(19) United States
(12) Patent Application Publication
(10) Pub. No.: US 2022/0204697 A1
(43) Pub. Date: Jun. 30, 2022

(54) POLYMER AND RESIN COMPOSITION THEREOF

(71) Applicant: INDUSTRIAL TECHNOLOGY RESEARCH INSTITUTE, Hsinchu (TW)

(72) Inventors: Jyh-Long JENG, New Taipei City (TW); Jeng-Yu TSAI, Chiayi City (TW); Wei-Ta YANG, Taoyuan City (TW)

(73) Assignee: INDUSTRIAL TECHNOLOGY RESEARCH INSTITUTE, Hsinchu (TW)

(21) Appl. No.: 17/139,088

(22) Filed: Dec. 31, 2020

(51) Int. Cl. C08G 73/10; G03F 7/038; G03F 7/028

(52) U.S. Cl. CPC C08G 73/1053; G03F 7/028; G03F 7/0387; C08G 73/1042

(57) ABSTRACT

A polymer and a resin composition thereof are provided. The polymer includes a first repeat unit represented by Formula (I) and a second repeat unit represented by Formula (II)

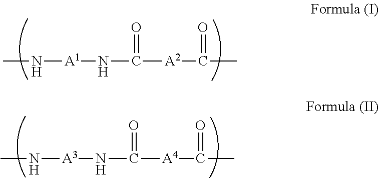

wherein A¹ is C₂₄₋₄₈ alkylene, C₂₄₋₄₈ alkenylene, C₂₄₋₄₈ alkynylene, C₂₄₋₄₈ alicyclic alkylene, C₂₄₋₄₈ alicyclic alkenylene, or C₂₄₋₄₈ alicyclic alkynylene. A² and A⁴, independently having at least one reactive group, are independently C₆₋₂₅ arylene, C₄₋₈ cycloalkylene, C₅₋₂₅ heteroarylene, divalent C₇₋₂₅ alkylaryl, divalent C₇₋₂₅ acylaryl, divalent C₆₋₂₅ aryl ether, divalent C₇₋₂₅ acyloxyaryl, or divalent C₆₋₂₅ sulfonylaryl; and, A³ is substituted or unsubstituted C₆₋₂₅ arylene, C₄₋₈ cycloalkylene, C₅₋₂₅ heteroarylene, divalent C₇₋₂₅ alkylaryl, divalent C₇₋₂₅ acylaryl, divalent C₆₋₂₅ aryl ether, divalent C₇₋₂₅ acyloxyaryl, or divalent C₆₋₂₅ sulfonylaryl.

### TECHNICAL FIELD

The disclosure relates to a polymer and resin composition thereof.

### BACKGROUND

With the advent of 5 g high frequency transmission, the direction of development efforts will focus on electronic products with a three-dimensional stack package structure and/or increased integration density, in order to achieve the advantages higher transmission speed and a lower delay time. As a result, insulating materials having low dielectric coefficient (Dk) and dielectric loss factor (Df) are desired.

Due to its excellent thermal stability and good mechanical, electrical, and chemical properties, polyimide (PI) is widely used in the semiconductor and display industries. However, conventional photosensitive polyimide insulating resin materials are apt to cause signal delay or loss in high frequency applications due to the high dielectric coefficient and dielectric dissipation factor of epoxy resin. In particular, it is important to maintain the signal transmission speed and quality for high frequency communication and computing electronic products.

Accordingly, a novel photosensitive resin material with low dielectric coefficient and dielectric dissipation factor is desired for solving the aforementioned problems.

### SUMMARY

The disclosure provides a polymer. According to embodiments of the disclosure, the polymer includes a first repeating unit and a second repeating unit. The first repeating unit has a structure represented by Formula (I), and the second repeating unit has a structure represented by Formula (II):

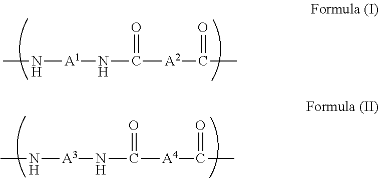

wherein A¹ can be C₂₄₋₄₈ alkylene group, C₂₄₋₄₈ alkenylene group, C₂₄₋₄₈ alkynylene group, C₂₄₋₄₈ alicyclic alkylene group, C₂₄₋₄₈ alicyclic alkenylene group, or C₂₄₋₄₈ alicyclic alkynylene group. A² and A⁴ can be independently C₆₋₂₅ arylene group having at least one reactive functional group, C₄₋₈ cycloalkylene group having at least one reactive functional group, C₅₋₂₅ heteroarylene group having at least one reactive functional group, divalent C₇₋₂₅ alkylaryl group having at least one reactive functional group, divalent C₇₋₂₅ acylaryl group having at least one reactive functional group, divalent C₆₋₂₅ aryl ether group having at least one reactive functional group, divalent C₇₋₂₅ acyloxyaryl group having at least one reactive functional group, or divalent C₆₋₂₅ sulfonylaryl having at least one reactive functional group. The reactive functional group is

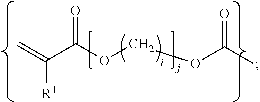

i can be 1, 2, 3, or 4; j can be 1, 2, 3, 4, 5, 6, 7, 8, 9, or 10; and, R¹ can be hydrogen or methyl. A³ can be substituted or non-substituted C₆₋₂₅ arylene group, substituted or non-substituted C₄₋₈ cycloalkylene group, substituted or non-substituted C₅₋₂₅ heteroarylene group, substituted or non-substituted divalent C₇₋₂₅ alkylaryl group, substituted or non-substituted divalent C₇₋₂₅ acylaryl group, substituted or non-substituted divalent C₆₋₂₅ aryl ether group, substituted or non-substituted divalent C₇₋₂₅ acyloxyaryl group, or substituted or non-substituted divalent C₆₋₂₅ sulfonylaryl group.

According to embodiments of the disclosure, the disclosure also provides a resin composition. According to embodiments of the disclosure, the resin composition includes the aforementioned polymer, and a photo-initiator.

A detailed description is given in the following embodiments.

### DETAILED DESCRIPTION

The polymer and resin composition thereof of the disclosure are described in detail in the following description. In the following detailed description, for purposes of explanation, numerous specific details and embodiments are set forth in order to provide a thorough understanding of the present disclosure. The specific elements and configurations described in the following detailed description are set forth in order to clearly describe the present disclosure. It will be apparent, however, that the exemplary embodiments set forth herein are used merely for the purpose of illustration, and the inventive concept may be embodied in various forms without being limited to those exemplary embodiments. As used herein, the term “about” in quantitative terms refers to plus or minus an amount that is general and reasonable to persons skilled in the art.

As used herein, the term “about” in quantitative terms refers to plus or minus an amount that is general and reasonable to persons skilled in the art.

Moreover, the use of ordinal terms such as “first”, “second”, “third”, etc., in the disclosure to modify an element does not by itself connote any priority, precedence, or order of one claim element over another or the temporal order in which it is formed, but are used merely as labels to distinguish one claim element having a certain name from another element having the same name (but for use of the ordinal term) to distinguish the claim elements.

The disclosure provides a polymer and a resin composition employing the same. The polyamic ester (PAE) having low dielectric coefficient (Dk) and low dielectric loss factor (Df) can be prepared by introducing the specific diamine and a structure having an acrylate group derived from the specific dianhydride into a main chain of the polymer of the disclosure. It should be noted that the resin composition of the disclosure can be patterned by a common lithography process and cured by a common baking process (setting temperature at or below 250° C.). The obtained cured layer exhibits superior mechanical strength, resolution, electrical properties, chemical resistance and thermal tolerance. In addition, the obtained cured layer exhibits low dielectric coefficient (Dk) and low dielectric loss factor (Df) at high frequency (at more than 10 GHz) and meets the requirement of patterned insulating material used in advanced 5 G high frequency system.

According to embodiments of the disclosure, the polymer includes first repeating unit and second repeating unit. the first repeating unit having a structure represented by Formula (I), and the second repeating unit having a structure represented by Formula (II):

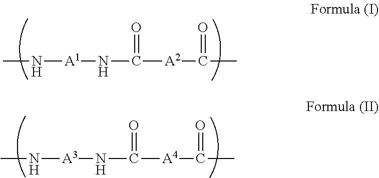

wherein A¹ can be C₂₄₋₄₈ alkylene group, C₂₄₋₄₈ alkenylene group, C₂₄₋₄₈ alkynylene group, C₂₄₋₄₈ alicyclic alkylene group, C₂₄₋₄₈ alicyclic alkenylene group, or C₂₄₋₄₈ alicyclic alkynylene group. A² and A⁴ can be independently C₆₋₂₅ arylene group having at least one reactive functional group, C₄₋₈ cycloalkylene group having at least one reactive functional group, C₅₋₂₅ heteroarylene group having at least one reactive functional group, divalent C₇₋₂₅ alkylaryl group having at least one reactive functional group, divalent C₇₋₂₅ acylaryl group having at least one reactive functional group, divalent C₆₋₂₅ aryl ether group having at least one reactive functional group, divalent C₇₋₂₅ acyloxyaryl group having at least one reactive functional group, or divalent C₆₋₂₅ sulfonylaryl having at least one reactive functional group. The reactive functional group is

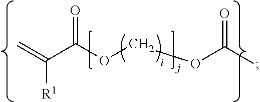

i can be 1, 2, 3, or 4; j can be 1, 2, 3, 4, 5, 6, 7, 8, 9, or 10; and, R¹ can be hydrogen or methyl. A³ can be substituted or non-substituted C₆₋₂₅ arylene group, substituted or non-substituted C₄₋₈ cycloalkylene group, substituted or non-substituted C₅₋₂₅ heteroarylene group, substituted or non-substituted divalent C₇₋₂₅ alkylaryl group, substituted or non-substituted divalent C₇₋₂₅ acylaryl group, substituted or non-substituted divalent C₆₋₂₅ aryl ether group, substituted or non-substituted divalent C₇₋₂₅ acyloxyaryl group, or substituted or non-substituted divalent C₆₋₂₅ sulfonylaryl. According to embodiments of the disclosure, in addition to at least one reactive functional group, the hydrogen bonded with the carbon of A² and A⁴ can be optionally replaced with fluorine, C₁₋₆ alkyl group, or C₁₋₆ fluoroalkyl group.

According to embodiments of the disclosure, the number of the first repeating unit of the polymer can be 1 to 2,000 (such as 2 to 1,800, 5 to 1,500, or 10 to 1,200), and the number of the first repeating unit of the polymer is 1 to 18,000 (such as 2 to 16000, 5 to 13,500, or 10 to 11,000). According to embodiments of the disclosure, the number ratio of the first repeating unit to the second repeating unit can be about 1:9 to 1:1, such as about 1:8, 1:7, 1:6, 1:5, 1:4, 1:3, or 1:2. When the number of the first repeating unit is too low, the polymer would have a low number of moieties having low polarity, resulting in that the resin composition is not apt to be developed, and the cured product of the resin composition exhibits high dielectric loss factor. When the number of the first repeating unit is too high, the polymer would have a low number of side-chain reactive functional group, resulting in that the obtained polymer exhibits high solubility and the cured product of the resin composition exhibits poor mechanical strength, thermal tolerance and inferior chemical resistance.

According to embodiments of the disclosure, the intrinsic viscosity of the polymer can be about 0.1 to 0.5, and the intrinsic viscosity of the oligomer or polymer of the disclosure can be determined by Ostwald viscometer.

According to embodiments of the disclosure, A¹ in the first repeating unit can be a linear, branched, or branched cyclic group and can have a chemical structure of, and A¹ has a chemical structure of —CₙH₂ₙ—, —CₙH₂₍ₙ₋₁₎—, —CₙH₂₍ₙ₋₂₎—, —CₙH₂₍ₙ₋₃₎—, —CₙH₂₍ₙ₋₄₎—, —CₙH₂₍ₙ₋₅₎—, or —CₙH₂₍ₙ₋₅₎—, wherein n is 24 to 48 (such as 25, 26, 27, 28, 29, 30, 31, 32, 33, 34, 35, 36, 37, 38, 39, 40, 41, 42, 43, 44, 45, 46, or 47).

According to embodiments of the disclosure, A¹ in the first repeating unit can be

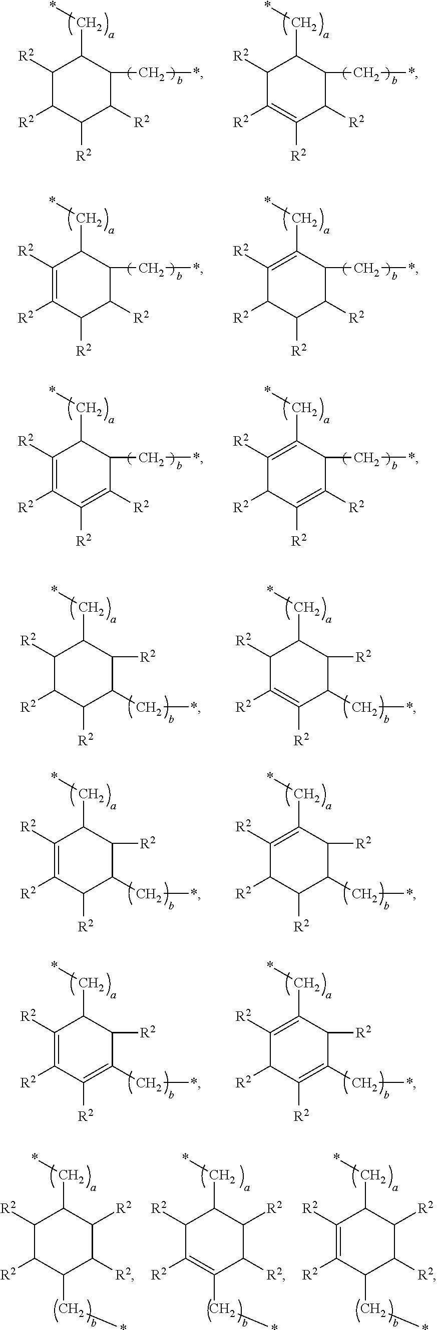

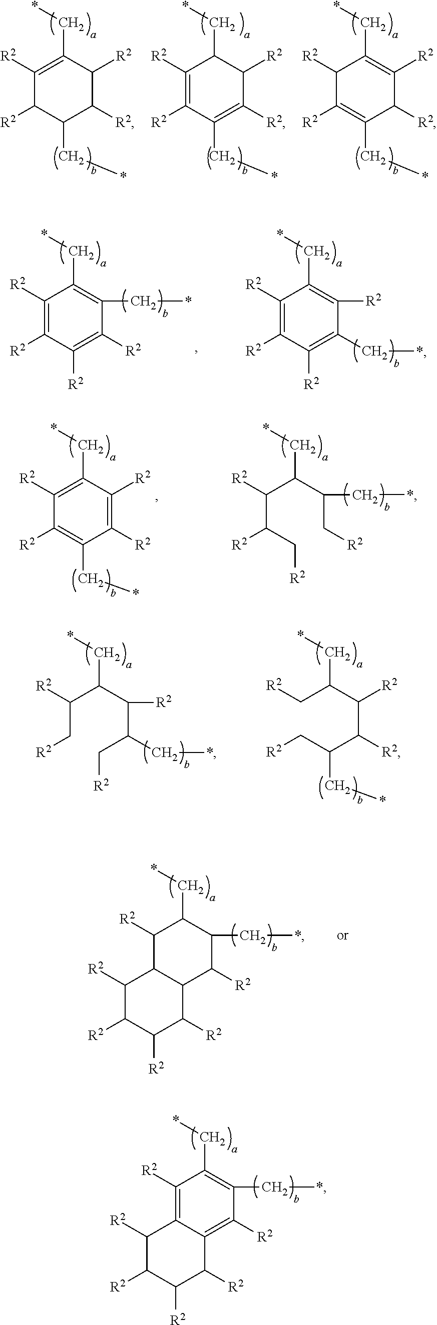

wherein A¹ is connected to nitrogen by the location represented by *; 12≥a≥4; 12≥b≥4; R² are independently hydrogen, C₄₋₁₀ alkyl group, C₄₋₁₀ alkenyl group, or C₄₋₁₀ alkynyl group. A¹ has 24 to 48 carbon atoms. According to embodiments of the disclosure, at least one R² of A¹ is not hydrogen (i.e. each of at least one R² is C₄₋₁₀ alkyl group, C₄₋₁₀ alkenyl group, or C₄₋₁₀ alkynyl). According to embodiments of the disclosure, at least two R² of A¹ are not hydrogen (i.e. each of at least two R² is C₄₋₁₀ alkyl group, C₄₋₁₀ alkenyl group, or C₄₋₁₀ alkynyl). According to embodiments of the disclosure, at least three of R² of A¹ are not hydrogen (i.e. each of at least three R² is C₄₋₁₀ alkyl group, C₄₋₁₀ alkenyl group, or C₄₋₁₀ alkynyl). When the number of R², which is C₄₋₁₀ alkyl group, C₄₋₁₀ alkenyl group, or C₄₋₁₀ alkynyl, is relatively high, the first repeating unit is more apt to serve as a structure with low polarity, thereby increasing the solubility of the polymer. According to embodiments of the disclosure, A¹ can be

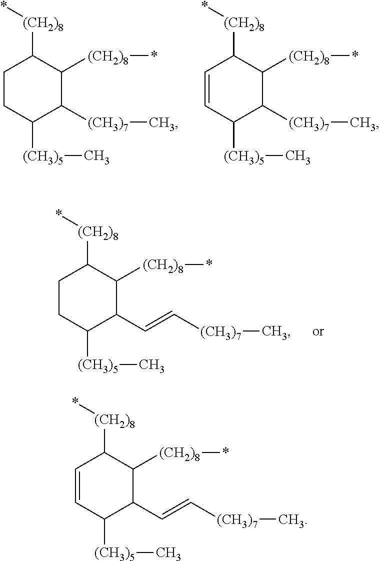

According to embodiments of the disclosure, in the first repeating unit, A² can be independently

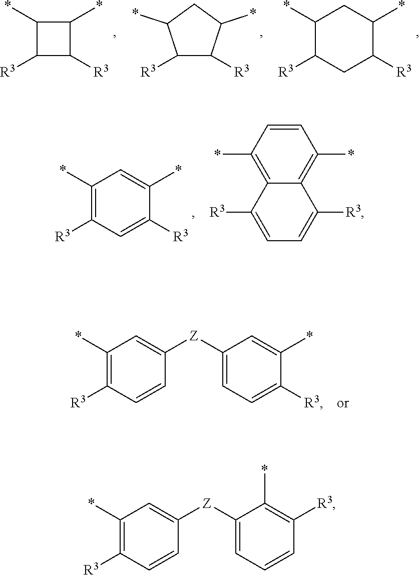

wherein A² is connected to nitrogen by the location represented by *; R³ is independently carboxyl, or

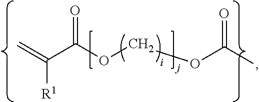

and at least one R³ is

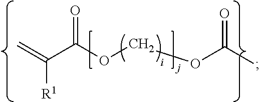

is 1, 2, 3, or 4; j is 1, 2, 3, 4, 5, 6, 7, 8, 9, or 10; R¹ is hydrogen or methyl; Z is single bond, —O—, —SO₂—, —C(CH₃)₂—, —C(CF₃)₂—,

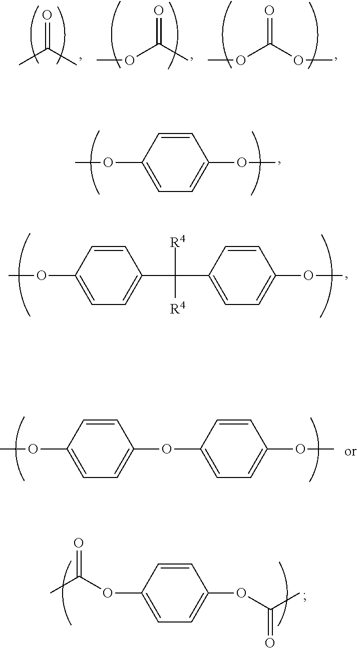

and, R⁴ is hydrogen, C₁₋₆ alkyl group, or C₁₋₆ fluoroalkyl group.

According to embodiments of the disclosure, C₁₋₁₀ alkyl group can be linear or branched alkyl group. For example, C₁₋₁₀ alkyl group can be methyl, ethyl, propyl, butyl, pentyl, hexyl, heptyl, octyl, or an isomer thereof. According to embodiments of the disclosure, C₁₋₆ fluoroalkyl can be an alkyl group which a part of or all hydrogen atoms bonded on the carbon atom are replaced with fluorine atoms and C₁₋₆ fluoroalkyl group can be linear or branched, such as fluoromethyl, fluoroethyl, fluoropropyl, fluorobutyl, fluoropentyl, fluorohexyl, or an isomer thereof. Herein, fluoromethyl group can be monofluoromethyl group, difluoromethyl group or trifluoromethyl group, and fluoroethyl can be monofluoroethyl group, difluoroethyl group, trifluoroethyl group, tetrafluoroethyl, or perfluoroethyl. According to embodiments of the disclosure, alkylene group can be linear or branched alkylene group.

According to embodiments of the disclosure, the first repeating unit can be

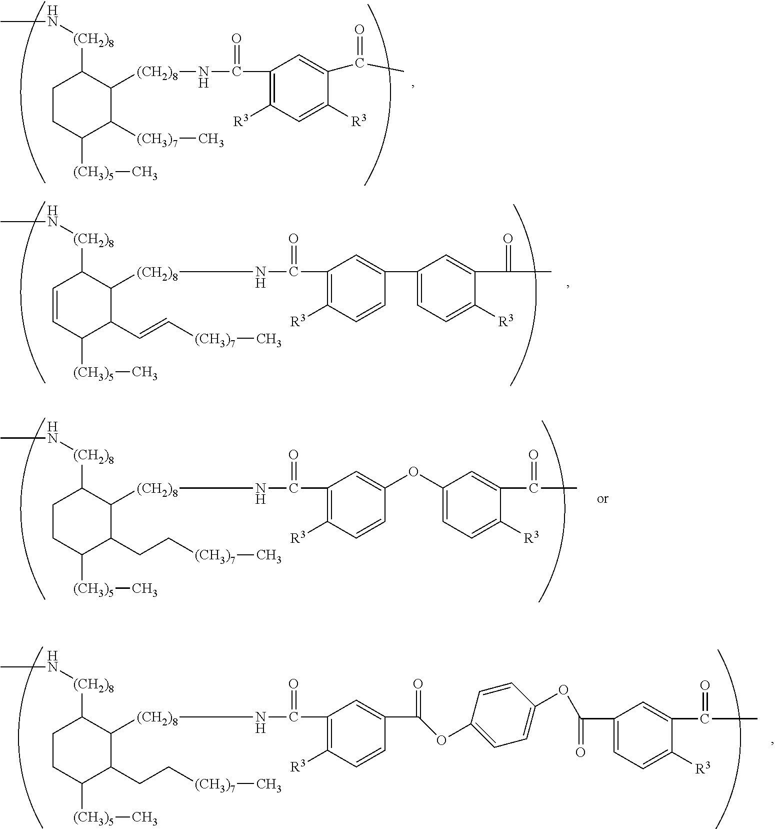

wherein R³ are independently carboxyl, or

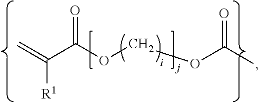

and at least one R³ is

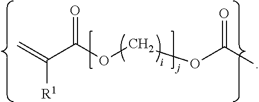

According to embodiments of the disclosure, A³ of the second repeating unit can be

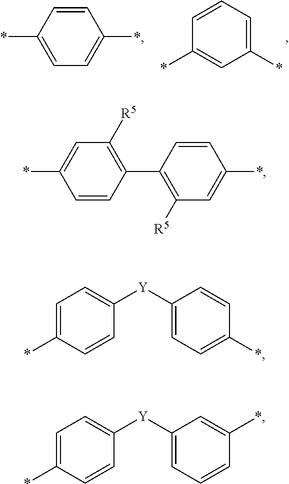

wherein A³ is connected to nitrogen by the location represented by *; R⁵ can be hydrogen, C₁₋₆ alkyl group, or C₁₋₆ fluoroalkyl group; Y can be single bond, —O—, —C(CH₃)₂—, —C(CF₃)₂—,

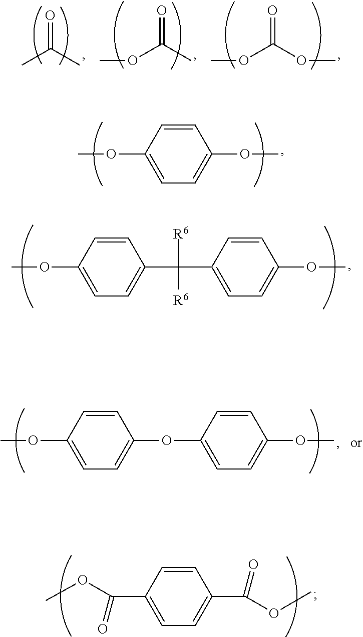

and, R⁶ can be hydrogen, C₁₋₆ alkyl group, or C₁₋₆ fluoroalkyl group.

According to embodiments of the disclosure, A⁴ of the second repeating unit can be independently

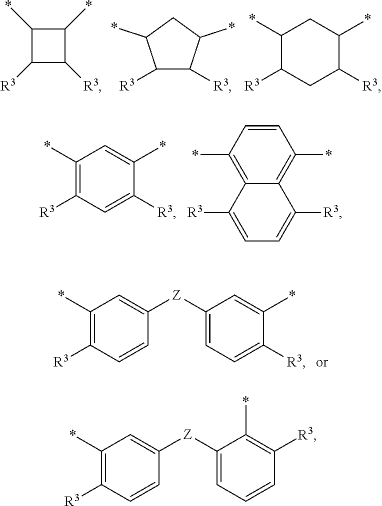

wherein A⁴ is connected to nitrogen by the location represented by *; R³ are independently carboxyl, or

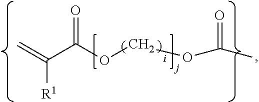

and at least one R³ is

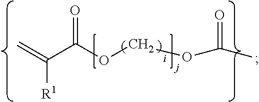

i is 1, 2, 3, or 4; j is 1, 2, 3, 4, 5, 6, 7, 8, 9, or 10; R¹ is hydrogen or methyl; Z is single bond, —O—, —SO₂—, —C(CH₃)₂—, —C(CF₃)₂—,

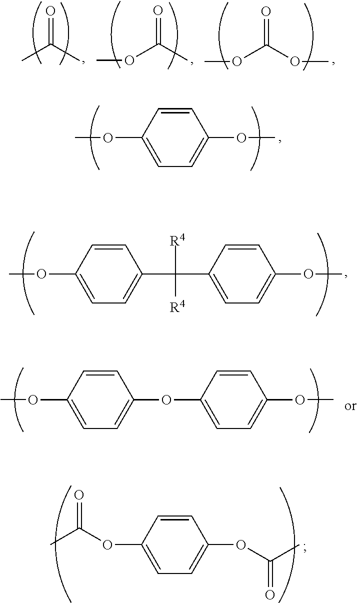

and, R⁴ is hydrogen, C₁₋₆ alkyl group, or C₁₋₆ fluoroalkyl group.

According to embodiments of the disclosure, the second repeating unit can be

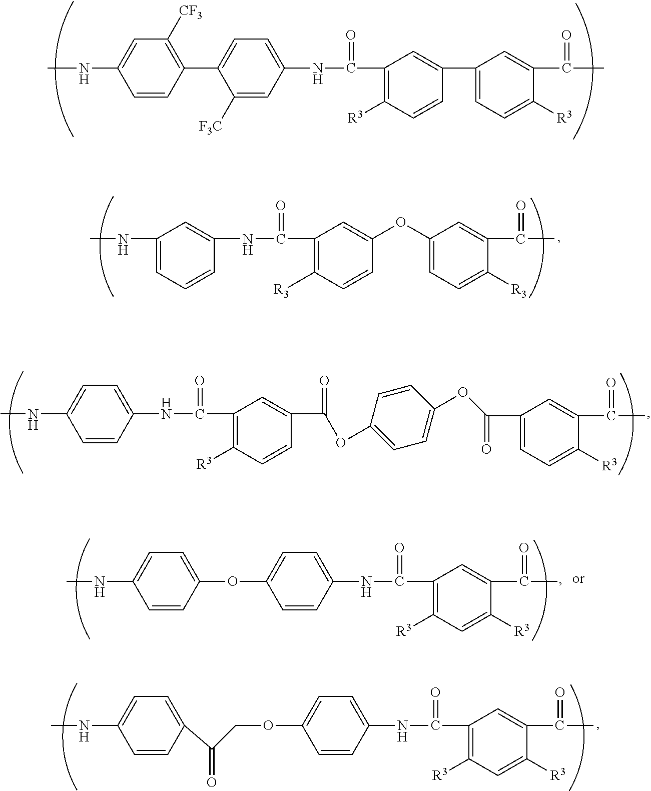

wherein R³ is independently carboxyl, or

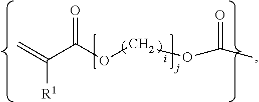

and at least one R³

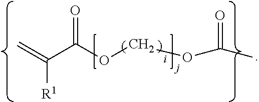

According to embodiments of the disclosure, the polymer preparation of the method can include the following steps. First, a dianhydride compound is provided. Next, the dianhydride compound is reacted with a compound having an acrylate group, obtaining a compound having at least one acrylate group. Next, the compound having at least one acrylate group is reacted with a first diamine and a second diamine simultaneously, obtaining the polymer of the disclosure. According to embodiments of the disclosure, the ratio of the mole of the compound having at least one acrylate group to the total mole of the first diamine and the second diamine can be about 1:0.8 to 1:1.2. According to embodiments of the disclosure, the molar ratio of the first diamine to the second diamine can be about 1:9 to 1:1, such as about 1:8, 1:7, 1:6, 1:5, 1:4, 1:3, or 1:2.

According to embodiments of the disclosure, the compound having at least one acrylate group is reacted with the first diamine and the second diamine simultaneously, the compound having at least one acrylate group, the first diamine and the second diamine can be dissolved in a solvent, and the solution is subjected to a polymerization at a temperature of −10° C. to 40° C. According to embodiments of the disclosure, the solvent can be at least one component of ethylene glycol ether precursors, aromatic hydrocarbons, and ketones. That is to say, the solvent can be a single or a mixed organic solvent. According to embodiments of the disclosure, the solvent can be, but not limited to, ethyl lactate, cyclohexanone, cyclopentanone (CPN), triglyme, 1,3-dimethyl-2-imidazolidinone (DMI), N-methyl-2-pyrrolidone

(NMP), methyl ethyl ketone (MEK), N,N-dimethylacetamide (DMAc), γ-butyrolactone (GBL), N,N-dimethylformamide (DME), or dimethyl sulfoxide (DMSO).

According to embodiments of the disclosure, the dianhydride compound can be

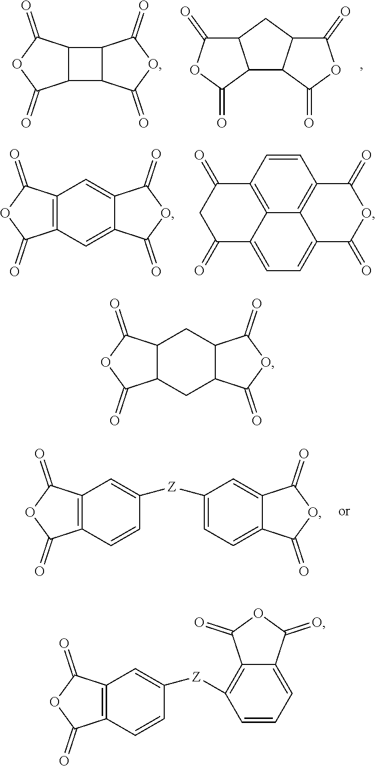

wherein Z is single bond, —O—, —SO₂—, —C(CH₃)₂—, —C(CF₃)₂—,

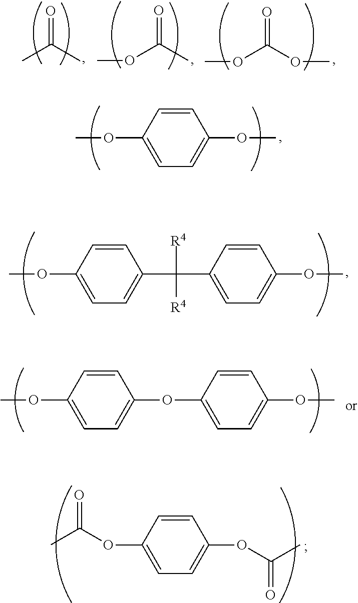

and, R⁴ is hydrogen, C₁₋₆ alkyl group, or C₁₋₆ fluoroalkyl group. According to embodiments of the disclosure, the dianhydride compound can be pyromellitic dianhydride (PMDA), 4,4′-(hexafluoroisopropylidene)-diphthalic anhydride (6FDA), 4,4′-oxydiphthalic anhydride (ODPA), 1,3-bis(4-aminophenoxy)benzene (RODA), 4,4′-biphthalic dianhydride (BPDA), 4,4′-bisphenol A dianhydride (BPADA), p-phenylene bis(trimellitate) dianhydride (TAHQ), or hydroquinnone diphtalic anhydride (HQDA), or a combination thereof.

According to embodiments of the disclosure, the first diamine can be

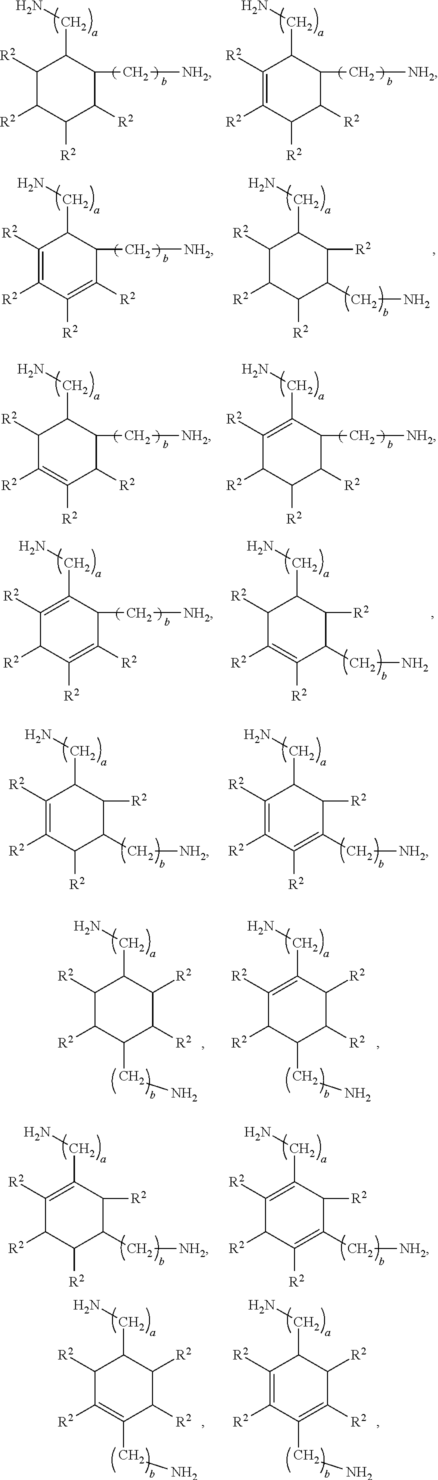

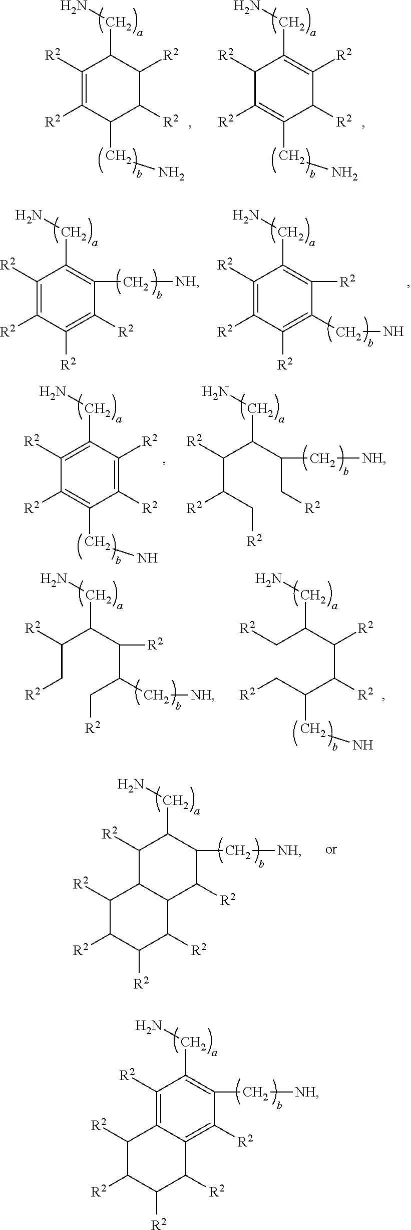

wherein 12a≥4; 12≥b≥4; R² are independently hydrogen, C₄₋₁₀ alkyl group, C₄₋₁₀ alkenyl group, or C₄₋₁₀ alkynyl group; at least two R² are not hydrogen. According to embodiments of the disclosure, the first diamine has 24 to 48 carbon atoms. According to embodiments of the disclosure, the second diamine can be

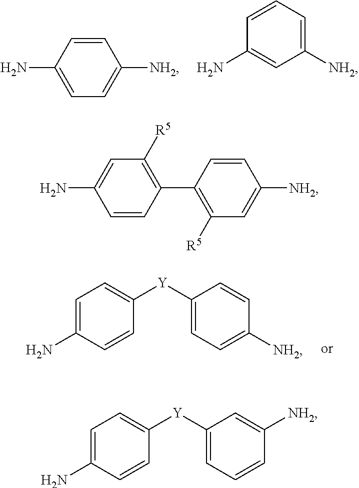

wherein R⁵ can be hydrogen, C₁₋₆ alkyl group, or C₁₋₆ fluoroalkyl group; Y can be single bond, —O—, —C(CH₃)₂—, —C(CF₃)₂—,

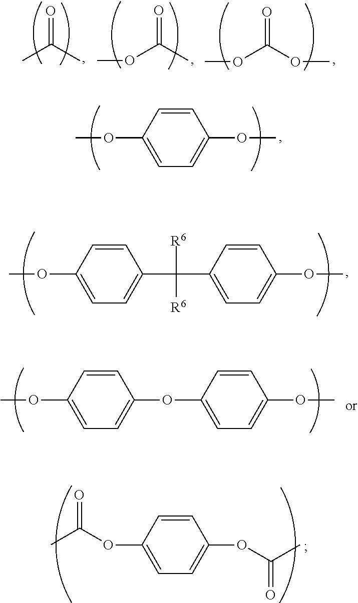

and, R⁶ can be hydrogen, C₁₋₆ alkyl group, or C₁₋₆ fluoroalkyl group. According to embodiments of the disclosure, the second diamine compound can be m-tolidine (m-TB), m-phenylenediamine (m-PDA), p-phenylenediamine (p-PDA), 4,4′-oxydianiline (4,4′-ODA), 3,4′-oxydianiline (3,4′-ODA), 1,4-bis(4-aminophenoxy)benzene (1,4-APB), 1,3-bis(4-aminophenoxy)benzene (1,3-APB), 1,2-bis(4-aminophenoxy)benzene (1,2-APB), 1,3-bis(3-aminophenoxy)benzene (APB-133), 2,5-bis(4-aminophenoxy)toluene, bis(4[4-aminophenoxy]phenyl)ether (BAPE), 4,4′-bis[4-aminophenoxy]biphenyl (BAPB), 2,2-bis[4-(4-aminophenoxy)]phenyl propane (BAPP), bis-(4-(4-aminophenoxy)phenyl sulfone (BAPS), 2,2′-bis(trifluoromethyl) 4,4′-diaminobiphenyl (TFMB), 1,4-diaminobenzene (PPD), or a combination thereof.

According to other embodiments of the disclosure, the disclosure provides a resin composition, such as negative resin composition. The resin composition can be patterned by a common lithography process. The resin composition exhibits a high sensitivity, good resolution, low post-cure temperature, high film thickness retention rate, and high chemical resistance. In addition, the resin composition of the disclosure can be stored stably at room temperature.

The resin composition of the disclosure can include the polymer of the disclosure and a photo-initiator. According to embodiments of the disclosure, the amount of polymer can be 100 parts by weight, and the amount of photo-initiator can be about 1-15 parts by weight, such as 2 parts by weight, 3 parts by weight, 4 parts by weight, 5 parts by weight, 6 parts by weight, 7 parts by weight, 8 parts by weight, 9 parts by weight, 10 parts by weight, 11 parts by weight, 12 parts by weight, 13 parts by weight, or 14 parts by weight. When the amount of photo-initiator is too high, the resin composition is apt to be cured incompletely. When the amount of photo-initiator is too low, the cured product is apt to dissolve into developer due to the reduced cross-linking degree. According to embodiments of the disclosure, the photo-initiator can be benzoin-based compound, acetophenone-based compound, benzylketal-based compound, anthraquinone-based compound, or a combination thereof. According to embodiments of the disclosure, the initiator can be thioxanthone, benzoin, benzoin methyl ether, benzoin isopropyl ether, 2,2-dimethoxy-2-phenyl-acetophenone, 1, 1-dichloro acetophenone, 1-hydroxy cyclohexyl-phenyl-ketone, 2-methyl anthraquinone, 2-hydroxy-1-[4-(2-hydroxyethoxy)phenyl]-2-methyl-1-propanone, 2-benzyl-2-(dimethyl amino)-1-[4-(4-morpholinyl)phenyl]-1-butanone, 2-methyl -1-[4-(methylthio)phenyl]-2-(4-morpholinyl)-1-propanone, diethoxyacetophenone, 2-hydroxy-2-methyl-1-phenylpropan-1-one, 1-(4-isopropylphenyl)-2-hydroxy-2-methylpropan-1-one, 4-(2-hydroxyethoxy)phenyl-(2-hydroxy-2-propyl)ketone, benzophenone, methyl o-benzoylbenzoate, propanetrione-diphenyl-2-[O-(ethoxycarbonyl)oxime], 1-phenyl-2-(benzoyloxyimino)-1-propanone, 1,2-Octanedione, 1-[4-(phenylthio)phenyl]-, 2-(O-benzoyloxime), 2-((benzoyloxy)imino)-3-cyclopentyl-1-(4-(phenylthio)phenyl)propan-1-one (such as TR-PBG-305, TR-PBG-3057), 2-(acetoxyimino)-1-(4-(4-hydroxyethoxy)phenylthiophenyl)propan-1-one (such as NCI-930), or a combination thereof.

According to embodiments of the disclosure, the resin composition can further include a solvent, such that the polymer and the photo-initiator are dissolved in the solvent. According to embodiments of the disclosure, the solvent can be ethyl lactate, cyclohexanone, cyclopentanone (CPN), triglyme, 1,3-dimethyl-2-imidazolidinone (DMI), N-methyl-2-pyrrolidone (NMP), methyl ethyl ketone (MEK), N,N-dimethylacetamide (DMAc),y-butyrolactone (GBL), N,N-dimethylformamide (DMF), or dimethyl sulfoxide (DMSO). According to embodiments of the disclosure, the amount of solvent is not particularly limited as 2 0 long as the polymer and the photo-initiator can be dispersed therein. According to embodiments of the disclosure, the amount of solvent can be 50 parts by weight to 800 parts by weight.

According to embodiments of the disclosure, the resin composition can further include a compound having an acrylate group in order to react with the polymer to undergo a cross-linking reaction, thereby improving the mechanical strength, resolution, electrical properties, chemical resistance and thermal tolerance of the cured product of the resin composition. According to embodiments of the disclosure, the amount of compound having an acrylate group can be about 1-15 parts by weight, such as 2 parts by weight, 3 parts by weight, 4 parts by weight, 5 parts by weight, 6 parts by weight, 7 parts by weight, 8 parts by weight, 9 parts by weight, 10 parts by weight, 11 parts by weight, 12 parts by weight, 13 parts by weight, or 14 parts by weight. According to embodiments of the disclosure, the compound having an acrylate group can be ethoxylated hydroxyethyl methacrylate (EOHEMA), 4-hydroxybutyl acrylate (4HBA), 2-hydroxyethyl methacrylate (HEMA), 2-hydroxypropyl methacrylate (HPMA), 1,4-butanediol diacrylate (BDDA), 1,4-butanediol dimethacrylate (BDDMA), 1,3-butylene glycol diacrylate (BGDA), 1,3-butylene glycol dimethacrylate (BGDMA), diethylene glycol diacrylate (DEGDA), diethylene glycol dimethacrylate (DEGDMA), dipropylene glycol diacrylate (DPGDA), ethylene glycol dimethacrylate (EGDMA), ethoxylated bisphenol A diacrylate (EOBDA), 1,6-hexanediol diacrylate (HDDA), 1,6-hexanediol dimethacrylate (HDDMA), neopentyl glycol diacrylate (NPGDA), neopentyl glycol dimethacrylate (NPGDMA), tetraethylene glycol diacrylate (TEGDA), tetraethylene glycol dimethacrylate (TEGDMA), triethylene glycol diacrylate (3EGDA), tri ethylene glycol dimethacrylate (3EGDMA), tripropylene glycol diacrylate (TPGDA), pentaerythritol triacrylate, ethoxylated trimethylpropane triacrylate, dipentaerythritol pentaacrylate, ethoxylated pentaerythritol tetraacrylate, pentaerythritol tetraacrylate, dipentaerythritol hexaacrylate (DPHA), or a combination thereof.

According to embodiments of the disclosure, the resin composition of the disclosure can be subjected to a lithography process to form a patterned layer. The lithography process can include the following steps. The resin composition is coated on a suitable substrate, wherein the substrate can be silicon substrate, glass, or ITO glass. Further, any desired layer can be formed on the substrate at first. A suitable coating technique includes, but not limited to, spin coating, roller coating, screen coating, curtain coating, dip coating, and spray coating. In an embodiment of the disclosure, a coating can be pre-baked at 60° C.-120° C. for a few minutes to evaporate the solvent contained therein. Next, the coating is exposed to an irradiation with a photo-mask. The aforementioned irradiation includes, for example, an X-ray, electron beam, UV ray, visible ray, or any photo source suitable for being used as an irradiation source. After exposure, the coating is subsequently developed with an alkaline aqueous developer solution to remove the unexposed portion of said coating, obtaining a patterned layer. Finally, the patterned layer is subjected to a hard bake process. Developing can be accomplished by immersion, spraying, or other known developing methods. The patterned layer is subsequently washed with deionized water. Since the resin composition has the specific polymer of the disclosure, the layer (i.e. the cured product) formed via lithography process exhibits superior mechanical strength, resolution, electrical properties, chemical resistance and thermal tolerance. In addition, the obtained cured layer exhibits low dielectric coefficient (Dk) and low dielectric loss factor (Df) at high frequency (at more than 10 GHz) and meets the requirement of patterned insulating material used in advanced 5G high frequency system.

According to embodiments of the disclosure, the disclosure provides a layer, wherein the layer includes the cured product of the resin composition of the disclosure.

Below, exemplary embodiments will be described in detail so as to be easily realized by a person having ordinary knowledge in the art. The inventive concept may be embodied in various forms without being limited to the exemplary embodiments set forth herein.

### EXAMPLES

### Preparation of Polymer

### Preparation Example 1

160.41 g of p-phenylene bis(trimellitate) dianhydride (TAHQ), 91.55 g of 2-hydroxyethyl methacrylate (HEMA), and 377 g of γ-butyrolactone (GBL) were added into a reaction bottle and the result was stirred at room temperature. Next, 57.87 g of pyridine was added into the reaction bottle, and then the reaction bottle was heated to 60° C. After stirring for 16 hours, the reaction bottle was cooled to room temperature, obtaining a mixture. Next, 144.42 g of dicyclohexylcarbodiimide (DCC) was dissolved in 134 g of γ-butyrolactone (GBL), obtaining a dicyclohexylcarbodiimide solution. Next, the dicyclohexylcarbodiimide solution was dropwisely added into reaction bottle in an ice bath to mix with the mixture. After stirring for 10 minutes, 56.69 g of diamine (commercially available from Croda Japan Co., Ltd. with a trade number of Priamine 1075) and 49.04 g of 4,4′-oxydianiline (4,4′-ODA) (the molar ratio of Priamine 1075 to 4,4′-ODA is 3:7) (the total number of moles of Priamine 1075 and 4,4′-ODA to the number of moles of TAHQ is 1:1) (was dissolved in 295 g of γ-butyrolactone (GBL)) were added into the reaction bottle and then the result was stirred for 1 hour. After stirring at room temperature for 2 hours, ethanol (30 ml) was added into the reaction bottle for 1 hour. Next, 420 g of γ-butyrolactone (GBL) was added. After filtration, the collected filtrate was added into ethanol to perform a reprecipitation, and the precipitate was collected. The precipitate was washed with distilled water and then dried at 40° C. under vacuum for 3 days, obtaining Polymer (1).

### Preparation Example 2

147.1 g of 4,4′-biphthalic dianhydride (BPDA), 131.44 g of 2-hydroxyethyl methacrylate (HEMA), and 423 g of γ-butyrolactone (GBL) were added into a reaction bottle, and then stirred at room temperature. Next, 88.5 g of pyridine was added into the reaction bottle and then heated to 60° C. After stirring for 16 hours, the reaction bottle was cooled to room temperature, obtaining a mixture. Next, 206.33 g of dicyclohexylcarbodiimide (DCC) was dissolved in 149 g of γ-butyrolactone (GBL), obtaining a dicyclohexylcarbodiimide solution. Next, the dicyclohexylcarbodiimide solution was dropwisely added into reaction bottle in an ice bath to mix with the mixture. After stirring for 10 minutes, 27 g of diamine (commercially available from Croda Japan Co., Ltd. with a trade number of Priamine 1075) and 90.09 g of 4,4′-oxydianiline (4,4′-ODA) (the molar ratio of Priamine 1075 to 4,4′-ODA is 1:9) (the total number of moles of Priamine 1075 and 4,4′-ODA to the number of moles of BPDA was 1:1) (was dissolved in 295 g of γ-butyrolactone (GBL)) was added into reaction bottle and stirred for 1 hour. After stirring at room temperature for 2 hours, ethanol (30 ml) was added into the reaction bottle for 1 hour. Next, 420 g of γ-butyrolactone (GBL) was added. After filtration, the collected filtrate was added into ethanol to perform a reprecipitation, and the precipitate was collected. The precipitate was washed with distilled water and then dried at 40° C. under vacuum for 3 days, obtaining Polymer (2).

### Preparation Example 3

147.1 g of 4,4′-biphthalic dianhydride (BPDA), 131.44 g of 2-hydroxyethyl methacrylate (HEMA), and 423 g of γ-butyrolactone (GBL) were added into a reaction bottle, and then stirred at room temperature. Next, 83.05 g of pyridine was added into the reaction bottle and then heated to 60° C. After stirring for 16 hours, the reaction bottle was cooled to room temperature, obtaining a mixture. Next, 206.33 g of dicyclohexylcarbodiimide (DCC) was dissolved in 149 g of γ-butyrolactone (GBL), obtaining a dicyclohexylcarbodiimide solution. Next, the dicyclohexylcarbodiimide solution was dropwisely added into reaction bottle in an ice bath to mix with the mixture. After stirring for 10 minutes, 135 g of diamine (commercially available from Croda Japan Co., Ltd. with a trade number of Priamine 1075) and 50.05 g of 4,4′-oxydianiline (4,4′-ODA) (the molar ratio of Priamine 1075 to 4,4′-ODA is 5:5) (the ratio of the total number of moles of Priamine 1075 and 4,4′-ODA to the number of moles of BPDA was 1:1) (was dissolved in 295 g of γ-butyrolactone (GBL)) was added into reaction bottle and stirred for 1 hour. After stirring at room temperature for 2 hours, ethanol (30 ml) was added into the reaction bottle for 1 hour. Next, 420 g of γ-butyrolactone (GBL) was added. After filtration, the collected filtrate was added into ethanol to perform a reprecipitation, and the precipitate was collected. The precipitate was washed with distilled water and then dried at 40° C. under vacuum for 3 days, obtaining Polymer (3).

### Preparation Example 4

147.1 g of 4,4′-biphthalic dianhydride (BPDA), 134.44 g of 2-hydroxyethyl methacrylate (HEMA), and 423 g of γ-butyrolactone (GBL) were added into a reaction bottle, and then stirred at room temperature. Next, 83.05 g of pyridine was added into the reaction bottle and then heated to 60° C. After stirring for 16 hours, the reaction bottle was cooled to room temperature, obtaining a mixture. Next, 206.33 g of dicyclohexylcarbodiimide (DCC) was dissolved in 149 g of γ-butyrolactone (GBL), obtaining a dicyclohexylcarbodiimide solution. Next, the dicyclohexylcarbodiimide solution was dropwisely added into reaction bottle in an ice bath to mix with the mixture. After stirring for 10 minutes, 81 g of diamine (commercially available from Croda Japan Co., Ltd. with a trade number of Priamine 1075) and 74.30 g of m-tolidine (m-TB) (the mole of Priamine 1075 tom-TB was 3:7) (the ratio of the total number of moles of Priamine 1075 and 4,4′-ODA to the number of mole of BPDA was 1:1) (was dissolved in 319 g of γ-butyrolactone (GBL)) was added into reaction bottle and stirred for 1 hour. After stirring at room temperature for 2 hours, ethanol (30 ml) was added into the reaction bottle for 1 hour. Next, 463 g of γ-butyrolactone (GBL) was added. After filtration, the collected filtrate was added into ethanol to perform a reprecipitation, and the precipitate was collected. The precipitate was washed with distilled water and then dried at 40° C. under vacuum for 3 days, obtaining Polymer (4).

### Comparative Preparation Example 1

147.1 g of 4,4′-biphthalic dianhydride (BPDA), 131.44 g of 2-hydroxyethyl methacrylate (HEMA), and 423 g of γ-butyrolactone (GBL) were added into a reaction bottle, and then stirred at room temperature. Next, 83.05 g of pyridine was added into the reaction bottle and then heated to 60° C. After stirring for 16 hours, the reaction bottle was cooled to room temperature, obtaining a mixture. Next, 206.33 g of dicyclohexylcarbodiimide (DCC) was dissolved in 149 g of γ-butyrolactone (GBL), obtaining a dicyclohexylcarbodiimide solution. Next, the dicyclohexylcarbodiimide solution was dropwisely added into reaction bottle in an ice bath to mix with the mixture. After stirring for 10 minutes, 100.1 g of 4,4′-oxydianiline (4,4′-ODA) (was dissolved in 319 g of γ-butyrolactone (GBL)) (the molar ratio of BPDA to 4,4′-ODA was 1:1) was added into reaction bottle and stirred for 1 hour. After stirring at room temperature for 2 hours, ethanol (30m1) was added into the reaction bottle for 1 hour. Next, 463 g of γ-butyrolactone (GBL) was added. After filtration, the collected filtrate was added into ethanol to perform a reprecipitation, and the precipitate was collected. The precipitate was washed with distilled water and then dried at 40° C. under vacuum for 3 days, obtaining Polymer (5).

### Comparative Preparation Example 2

147.1 g of 4,4′-biphthalic dianhydride (BPDA), 131.44 g of 2-hydroxyethyl methacrylate (HEMA), and 423 g of γ-butyrolactone (GBL) were added into a reaction bottle, and then stirred at room temperature. Next, 83.05 g of pyridine was added into the reaction bottle and then heated to 60° C. After stirring for 16 hours, the reaction bottle was cooled to room temperature, obtaining a mixture. Next, 206.33 g of dicyclohexylcarbodiimide (DCC) was dissolved in 149 g of γ-butyrolactone (GBL), obtaining a dicyclohexylcarbodiimide solution. Next, the dicyclohexylcarbodiimide solution was dropwisely added into reaction bottle in an ice bath to mix with the mixture. After stirring for 10 minutes, 162 g of diamine (commercially available from Croda Japan Co., Ltd. with a trade number of Priamine 1075) and 60.06 g of 4,4′-oxydianiline (4,4′-ODA) (the molar ratio of Priamine 1075 to 4,4′-ODA is 60:40) (the ratio of the total number of moles of Priamine 1075 and 4,4′-ODA to the number of moles of BPDA was 1:1) (was dissolved in 295 g of γ-butyrolactone (GBL)) was added into reaction bottle and stirred for 1 hour. After stirring at room temperature for 2 hours, ethanol (30 ml) was added into the reaction bottle for 1 hour. Next, 420 g of γ-butyrolactone (GBL) was added. After filtration, the collected filtrate was added into ethanol to perform a reprecipitation, and the precipitate was collected. The precipitate was washed with distilled water and then dried at 40° C. under vacuum for 3 days, obtaining Polymer (6).

### Comparative Preparation Example 3

160.41 g of p-phenylene bis(trimellitate) dianhydride (TAHQ), 56.69 g of diamine (commercially available from Croda Japan Co., Ltd. with a trade number of Priamine 1075), 21.02 g of 4,4′-oxydianiline (4,4′-ODA) (the molar ratio of Priamine 1075 to 4,4′-ODA is 3:7) (the molar ratio of of Priamine 1075 and 4,4′-ODA to TAHQ was 1:1), and 714.36 g of N-methyl-2-pyrrolidone (NMP) were added into a reaction bottle. 70 g of xylene was added into the reaction bottle at room temperature and the result was heated to 180° C. and stirred for 5 hours. Herein, a precipitate was observed soon, and it means that obtained Polymer (7) exhibited poor solubility.

### Comparative Preparation Example 4

147.1 g of 4,4′-biphthalic dianhydride (BPDA), 189 g of diamine (commercially available from Croda Japan Co., Ltd. with a trade number of Priamine 1075), 30.03 g of 4,4′-oxydianiline (4,4′-ODA) (the molar ratio of Priamine 1075 to 4,4′-ODA is 7:3) (the ratio of the total number of moles of Priamine 1075 and 4,4′-ODA to the number of moles of BPDA was 1:1), and 1098 g of N-methyl-2-pyrrolidone (NMP) were added into a reaction bottle. 70 g of xylene was added into the reaction bottle at room temperature and the result was heated to 180° C. After stirring for 5 hours, the result was cooled to perform a precipitation. The precipitate was washed with distilled water and then dried at 40° C. under vacuum for 3 days, obtaining Polymer (8).

The components of polymer disclosed in Preparation Examples 1-4 and Comparative Preparation Example 1-4 were shown in Table. 1. The amount of component is represented by mole by weight (the amount of dianhydride (TAHQ or BPDA) is 100 parts by mole).

TABLE 1

| | | first diamine | | |
|---|---|---|---|---|
| | | (Priamine | second | reacting |
| | dianhydride | 1075) | diamine/ | dianhydride |
| | compound/parts | (parts by | parts by | compound with |
| | by weight | weight) | weight | HEMA at first |
| Preparation | TAHQ/100 | 30 | 4,4′-ODA/ | Yes |
| Example 1 | | | 70 | |
| Preparation | BPDA/100 | 10 | 4,4′-ODA/ | Yes |
| Example 2 | | | 90 | |
| Preparation | BPDA/100 | 50 | 4,4′-ODA/ | Yes |
| Example 3 | | | 50 | |
| Preparation | BPDA/100 | 30 | m-TB/ | Yes |
| Example 4 | | | 70 | |
| Comparative | BPDA/100 | 0 | 4,4′-ODA/ | Yes |
| Preparation | | | 100 | |
| Example 1 | | | | |
| Comparative | BPDA/100 | 60 | 4,4′-ODA/ | Yes |
| Preparation | | | 40 | |
| Example 2 | | | | |
| Comparative | TAHQ/100 | 30 | 4,4′-ODA/ | No |
| Preparation | | | 70 | |
| Example 3 | | | | |
| Comparative | BPDA/100 | 70 | 4,4′-ODA/ | No |
| Preparation | | | 30 | |
| Example 4 | | | | |

### Photosensitive Composition Preparation of

### Example 1

100 g of Polymer (1) of Preparation Example 1, 8 g of tetraethylene glycol dimethacrylate (TEGDMA), and 4 g of propanetrione-diphenyl-2-[O-(ethoxycarbonyl)oxime] (serving as photo-initiator) were dissolved in 80 g of N-methyl-2-pyrrolidone (NMP), obtaining Negative resin composition (1).

### Example 2

100 g of Polymer (2) of Preparation Example 2, 10 g of tetraethylene glycol dimethacrylate (TEGDMA), 3 g of propanetrione-diphenyl-2-[O-(ethoxycarbonyl)oxime] (serving as photo-initiator) were dissolved in 80 g of N-methyl-2-pyrrolidone (NMP), obtaining Negative resin composition (2).

### Example 3

100 g of Polymer (3) of Preparation Example 3, 20 g of tetraethylene glycol dimethacrylate (TEGDMA), 10 g of propanetrione-diphenyl-2-[O-(ethoxycarbonyl)oxime] (serving as photo-initiator) were dissolved in 80 g of N-methyl-2-pyrrolidone (NMP), obtaining Negative resin composition (3).

### Example 4

100 g of Polymer (4) of Preparation Example 1, 8 g of dipentaerythritol hexaacrylate (DPHA), 6 g of propanetrione-diphenyl-2-[O-(ethoxycarbonyl)oxime] (serving as photo-initiator) were dissolved in 80 g of N-methyl-2-pyrrolidone (NMP), obtaining Negative resin composition (4).

### Comparative Example 1

Comparative Example 1 was performed in the same manner as in Example 1, except that Polymer (1) was replaced with Polymer (5), obtaining Resin composition (5).

### Comparative Example 2

Comparative Example 2 was performed in the same manner as in Example 3, except that Polymer (3) was replaced with Polymer (6), obtaining Resin composition (6).

### Comparative Example 3

Comparative Example 3 was performed in the same manner as in Example 3, except that Polymer (3) was replaced with Polymer (7), obtaining Resin composition (7).

### Properties Test of Resin Composition

The resin compositions (1)-(7) were subjected to a lithography process, and the results were subjected to a resolution test. The lithography process included following steps. The resin compositions (1)-( ) were coated on a substrate individually, and then pre-baked at 110° C. for 2 minutes, obtaining a layer with a thickness of 2 μm. Next, the layer was irradiated with a light (with a wavelength of 250 nm-400 nm) from an un-filtered mercury arc lamp. Next, the layer was developed by cyclopentanone (CPN) solution for 60 seconds, and then washed with propylene glycol methyl ether acetate (PGMEA) for 30 seconds. Next, the layer was baked at 250° C. for 60 minutes, obtaining a cured product. The results of the resolution tests are represented by the minimum line widths/line spaces of the patterns of the cured product after being developed and dried, and the results are shown in Table 1. Next, the dielectric coefficient (Dk) and dielectric loss factor (Df) of the cured product of the compositions (1)-(7) were measured, and the cured product of the compositions (1)-(7) was subjected to a chemical resistance test, and the results are shown in Table 2. The dielectric coefficient (Dk) and dielectric loss factor (Df) were measured at a frequency of 10 GHz using a microwave dielectrometer (available from AET Corporation). The chemical resistance was determined by following steps. The layer was immersed in cyclopentanone (CPL) at 70° C. for 10 minutes, followed by washing with water for 5 minutes. Thereafter, when a deformation of shape or a variation of thickness of the layer was observed, the test was marked with X. Otherwise, it was marked with O.

TABLE 1

| | | dielectric | dielectric loss | chemical |
|---|---|---|---|---|
| | resolution (μm) | coefficient | factor | resistance |
| Example 1 | ~30 | 3.3 | 0.007 | ◯ |
| Example 2 | ~30 | 3.2 | 0.009 | ◯ |
| Example 3 | ~30 | 2.8 | 0.006 | ◯ |
| Example 4 | ~30 | 3.2 | 0.007 | ◯ |
| Comparative | ~30 | 3.6 | 0.013 | ◯ |
| Example 1 | | | | |
| Comparative | ~75 | 2.75 | 0.006 | X |
| Example 2 | | | | |
| Comparative | ~100 | 2.81 | 0.007 | X |
| Example 3 | | | | |

As shown in Table 1 and Table 2, when the number ratio of the first repeating unit to the second repeating unit of the polymer of the disclosure (i.e. the molar ratio of the first diamine and the second diamine) is between 1:9 to 5:5, the patterned layer prepared from the cured product of the resin composition employing the polymer (i.e. the resin compositions of Examples 1-4) exhibits superior resolution, low dielectric coefficient, low dielectric loss factor, and superior chemical resistance. In addition, when the polymer merely has the first repeating unit, the patterned layer prepared from the cured product of the resin composition employing the polymer (i.e. the resin composition of the Comparative Example 1) exhibits relatively high dielectric coefficient and dielectric loss factor. Furthermore, when the number ratio of the first repeating unit to the second repeating unit of the polymer of the disclosure (i.e. the molar ratio of the first diamine and the second diamine) is greater than 5:5, the patterned layer prepared from the cured product of the resin composition employing the polymer (i.e. the resin composition of Comparative Example 2) exhibits inferior resolution and chemical resistance. Furthermore, when the polymer is directly prepared by reacting the diamine (including the first diamine and second diamine) with dianhydride compound (i.e. the obtained polymer does not have the first repeating unit and the second repeating unit), the patterned layer prepared from the cured product of the resin composition employing the polymer (i.e. the resin composition of Comparative Example 3) exhibits inferior resolution and chemical resistance.

It will be clear that various modifications and variations can be made to the disclosed methods and materials. It is intended that the specification and examples be considered as exemplary only, with the true scope of the disclosure being indicated by the following claims and their equivalents.

What is claimed is:

1. A polymer, comprising a first repeating unit and a second repeating unit, and the first repeating unit has a structure represented by Formula (I), and the second repeating unit has a structure represented by Formula (II): 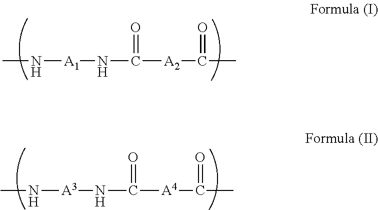
wherein A¹ is C₂₄₋₄₈ alkylene group, C₂₄₋₄₈ alkenylene, C₂₄₋₄₈ alkynylene, C₂₄₋₄₈ alicyclic alkylene, C₂₄₋₄₈ alicyclic alkenylene, or C₂₄₋₄₈ alicyclic alkynylene; A² and A⁴, independently having at least one reactive group, are independently C₆₋₂₅ arylene group, C₄₋₈ cycloalkylene group, C₅₋₂₅ heteroarylene group, divalent C₇₋₂₅ alkylaryl group, divalent C₇₋₂₅ acylaryl group, divalent C₆₋₂₅ aryl ether group, divalent C₇₋₂₅ acyloxyaryl group, or divalent C₆₋₂₅ sulfonylaryl group; the reactive functional group is 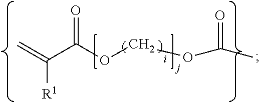
i is 1, 2, 3, or 4; j is 1, 2, 3, 4, 5, 6, 7, 8, 9, or 10; R¹ is hydrogen or methyl; and A³ is substituted or non-substituted C₆₋₂₅ arylene group, C₄₋₈ cycloalkylene group, C₅₋₂₅ heteroarylene group, divalent C₇₋₂₅ alkylaryl group, divalent C₇₋₂₅ acylaryl group, divalent C₆₋₂₅ aryl ether group, divalent C₇₋₂₅ acyloxyaryl group, or divalent C₆₋₂₅ sulfonylaryl group.

2. The polymer as claimed in claim 1, wherein A¹ is a linear, branched, or branched cyclic group and has a chemical structure of —CₙH₂ₙ—, —CₙH₂₍ₙ₋₁₎—, —CₙH₂₍ₙ₋₂₎—, —CₙH₂₍ₙ₋₃₎—, —CₙH₂₍ₙ₋₄₎—, —CₙH₂₍ₙ₋₅₎—, or —CₙH₂₍ₙ₋₅₎—, wherein n is 24 to 48.

3. The polymer as claimed in claim 1, wherein A¹ is 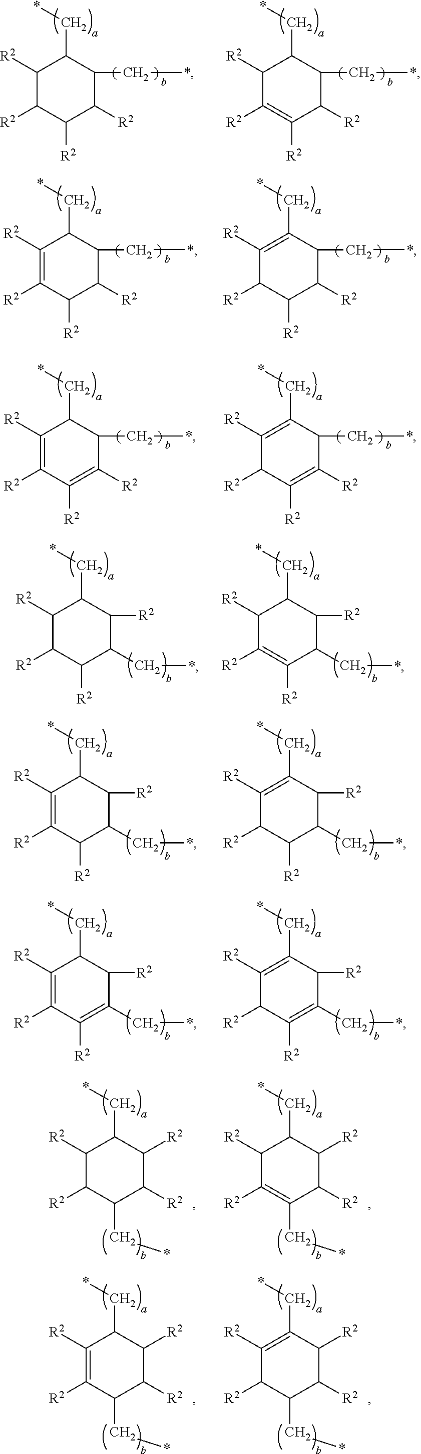 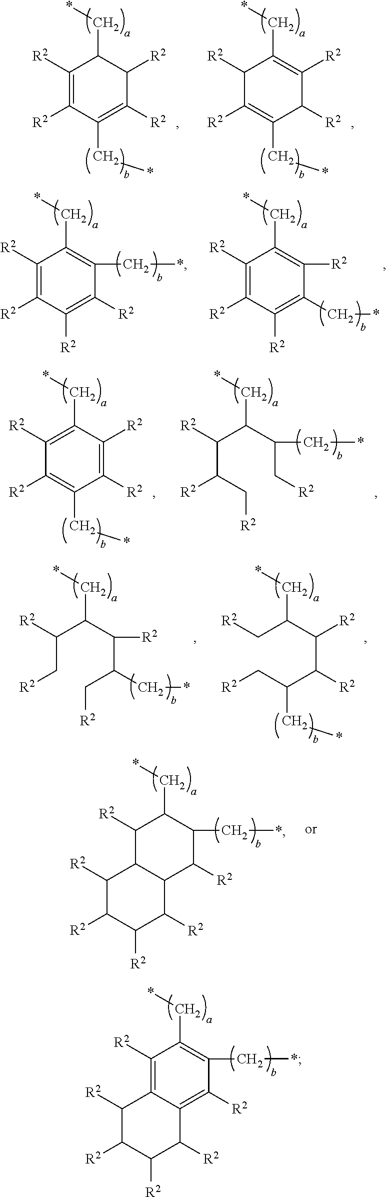
12≥a≥4; 12≥b≥4; R² is independently hydrogen, C₄₋₁₀ alkyl group, C₄₋₁₀ alkenyl group, or C₄₋₁₀ alkynyl group; at least two R² are not hydrogen; and, A¹ has 24 to 48 carbon atoms.

4. The polymer as claimed in claim 1, wherein the A² and A⁴ are independently 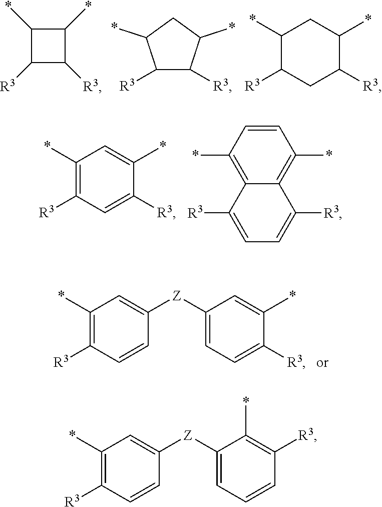
R³ is independently carboxyl, or 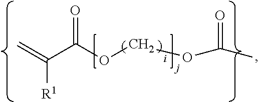
and at least one R³ is 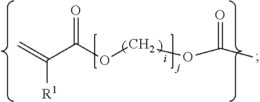
i is 1, 2, 3, or 4; j is 1, 2, 3, 4, 5, 6, 7, 8, 9, or 10; R¹ is hydrogen or methyl; Z is single bond, —O—, —SO₂—, —C(CH₃)₂—, —C(CF₃)₂—, 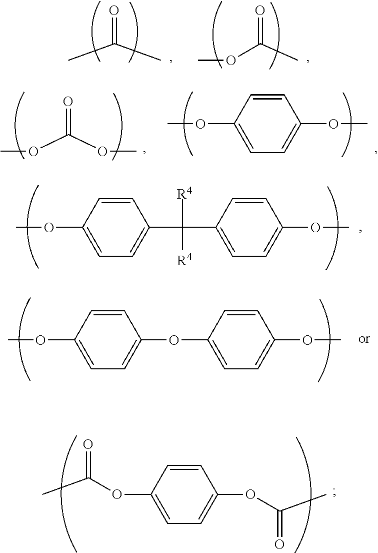
and, R⁴ is hydrogen, C₁₋₆ alkyl group, or C₁₋₆ fluoroalkyl group.

5. The polymer as claimed in claim 1, wherein A³ is 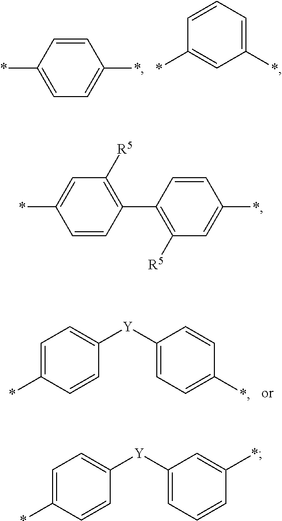
R⁵ is hydrogen, C₁₋₆ alkyl group, or C₁₋₆ fluoroalkyl group; Y is single bond, —O—, —C(CH₃)₂—, —C(CF₃)₂—, 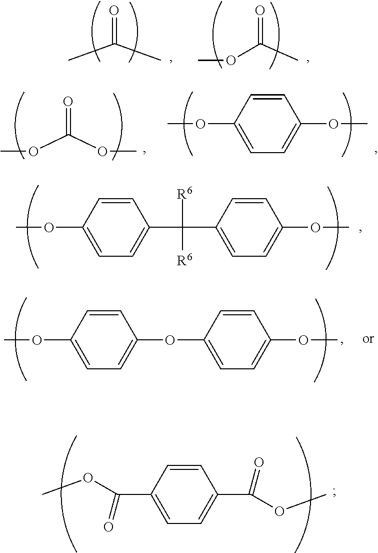
and, R⁶ is hydrogen, C₁₋₆ alkyl group, or C₁₋₆ fluoroalkyl group.

6. The polymer as claimed in claim 1, wherein the number ratio of the first repeating unit to the second repeating unit is 1:9 to 1:1.

7. A resin composition, comprising:
the polymer as claimed in claim 1; and
a photo-initiator.

8. The resin composition as claimed in claim 7, wherein the amount of polymer is 100 parts by weight, and the amount of photo-initiator is 1-15 parts by weight.

9. The resin composition as claimed in claim 7, wherein the photo-initiator is benzoin-based compound, acetophenone-based compound, benzylketal-based compound, anthraquinone-based compound, or a combination thereof.

10. The resin composition as claimed in claim 7, wherein the photo-initiator is thioxanthone, benzoin, benzoin methyl ether, benzoin isopropyl ether, 2,2-dimethoxy-2-phenyl-acetophenone, 1, 1-dichloro acetophenone, 1-hydroxy cyclohexyl-phenyl-ketone, 2-methyl anthraquinone, 2-hydroxy-1-[4-(2-hydroxyethoxy)phenyl]-2-methyl-1-propanone, 2-benzyl-2-(dimethylamino)-1-[4-(4-morpholinyl)phenyl]-1-butanone, 2-methyl-1-[4-(methylthio)phenyl]-2-(4-morpholinyl)-1-propanone, diethoxyacetophenone, 2-hydroxy-2-methyl-1-phenylpropan-1-one, 1-(4-isopropylphenyl)-2-hydroxy-2-methylpropan-1-one, 4-(2-hydroxyethoxy)phenyl-(2-hydroxy-2-propyl)ketone, benzophenone, methyl o-benzoylbenzoate, propanetrione-diphenyl-2-[O-(ethoxycarbonyl)oxime], or a combination thereof.

11. The resin composition as claimed in claim 7, further comprising:
a compound having an acrylate group, wherein the amount of the compound having an acrylate group is 1-15 parts by weight.

12. The resin composition as claimed in claim 11, wherein the compound having an acrylate group is ethoxylated hydroxyethyl methacrylate (EOHEMA), 4-hydroxybutyl acrylate (4HBA), 2-hydroxyethyl methacrylate (HEMA), 2-hydroxypropyl methacrylate (HPMA), 1,4-butanediol diacrylate (BDDA), 1,4-butanediol dimethacrylate (BDDMA), 1,3-butylene glycol diacrylate (BGDA), 1,3-butylene glycol dimethacrylate (BGDMA), diethylene glycol diacrylate (DEGDA), diethylene glycol dimethacrylate (DEGDMA), dipropylene glycol diacrylate (DPGDA), ethylene glycol dimethacrylate (EGDMA), ethoxylated bisphenol A diacrylate (EOBDA), 1,6-hexanediol diacrylate (HDDA), 1,6-hexanediol dimethacrylate (HDDMA), neopentyl glycol diacrylate (NPGDA), neopentyl glycol dimethacrylate (NPGDMA), tetraethylene glycol diacrylate (TEGDA), tetraethylene glycol dimethacrylate (TEGDMA), triethylene glycol diacrylate (3EGDA), triethylene glycol dimethacrylate (3EGDMA), tripropylene glycol diacrylate (TPGDA), pentaerythritol triacrylate, ethoxylated trimethylpropane triacrylate, dipentaerythritol pentaacrylate, ethoxylated pentaerythritol tetraacrylate, pentaerythritol tetraacrylate, dipentaerythritol hexaacrylate, or a combination thereof.
